(19) United States
(12) Patent Application Publication
(10) Pub. No.: US 2012/0160307 A1
(43) Pub. Date: Jun. 28, 2012

(54) DYE-SENSITIZED SOLAR CELL AND METHOD FOR MANUFACTURING THE SAME

(75) Inventors: Yuh-Lang LEE, Tainan City (TW); Ching-Lun Chen, Tainan City (TW); Chien-Heng Chen, Guanyin Township (TW)

(73) Assignee: National Cheng Kung University, Tainan City (TW)

(21) Appl. No.: 13/167,886

(22) Filed: Jun. 24, 2011

(30) Foreign Application Priority Data
Dec. 22, 2010 (TW) 099145182

(51) Int. Cl. H01L 31/0224; H01L 31/18; H01L 31/02

(52) U.S. Cl. 136/254; 156/146

(57) ABSTRACT

The present invention provides a dye-sensitized solar cell (DSSC), and a method for manufacturing the same. In the present invention, the DSSC comprises: a dye-sensitized semiconductor electrode, a counter electrode opposite to the dye-sensitized semiconductor electrode, and an electrolyte disposed between the dye-sensitized semiconductor electrode and the counter electrode. Herein, the dye-sensitized semiconductor electrode comprises: an anode; a TiO₂ layer disposed on the anode; and a dye absorbed to the TiO₂ layer. In addition, the counter electrode comprises: a first transparent substrate with a first transparent electrode formed thereon; and a Pt film disposed on the first transparent electrode, wherein the Pt film is formed with plural Pt nanoparticles, the diameters of the Pt nanoparticles are 1-8 nm, and the thickness of the Pt film is 0.5-3 nm.

### BACKGROUND OF THE INVENTION

1. Field of the Invention

The present invention relates to a dye-sensitized solar cell and a method for manufacturing the same and, more particularly, to a flexible dye sensitized solar cell, which has a counter electrode with high transmittance, and a method for manufacturing the same.

2. Description of Related Art

As the development of the industry and technology, the problems of the energy crisis and the environmental pollution are getting serious. In order to solve these problems, solar cells that can directly covert the energy of sunlight into electricity, are developed. In addition, since no pollutant gases such as CO₂ formed during the conversion process of the solar cells, the solar cells are considered as an eco-friendly device.

Recently, various solar cells, such as silicon solar cells, thin-film solar cells, and dye-sensitized solar cells, have been developed. Among these types of solar cells, the dye-sensitized solar cells (DSSCs) have the advantages of low cost and flexibility, and easiness for mass-production of large area DSSCs. In addition, since the counter electrode, an important component in the DSSC, acts as a role to transfer the electrons from external circuit back to the electrolyte and catalyzing the reduction of the electrolyte, a counter electrode with high electrochemical activity is indispensable to an efficient DSSC.

The procedure for forming the TiO₂ layer of the photoanode of the DSSC is usually performed under high temperature (>400° C.). However, owing to the low glass transition temperature of the plastic substrate, the plastic substrate cannot endure high temperature without damage. Hence, a metal substrate such as Ti substrate is suggested to replace the plastic substrate in the flexible DSSC. Moreover, when the Ti substrate is used in the photoanode, the counter electrode has to possess a high transparency since the DSSC should be illuminated through the counter electrode (back-side illumination).

As a conventional counter electrode of the DSSC, Platinum (Pt) is a widely used material due to its superior electrocatalytic activity. Various methods have been employed to prepare Pt counter electrodes. Among them, the thermal decomposition is the most commonly used one. However, the thermal decomposition is usually performed under high temperature (>400° C.), so thermal deposition is not suitable for processing plastic substrates with Pt counter electrodes thereon. As an alternative, electrodeposition, chemical reduction, or sputtering can also be utilized.

In addition, the thickness of the Pt film of the Pt counter electrode is usually more than 10 nm, so the transmittance of the Pt film is not high enough when the DSSC is illuminated through the counter electrode (i.e. back-side illumination).

Therefore, it is desirable to provide a Pt counter electrode possessing both high catalytic activity and high light transmittance to illuminate light through the backside. In addition, it is also desirable to provide a DSSC with an improved performance, and a method for manufacturing the same.

### SUMMARY OF THE INVENTION

The object of the present invention is to provide a dye-sensitized solar cell (DSSC), which has a counter electrode with both high catalytic activity and high light transmittance. Hence, the efficiency of the backside illumination of this DSSC can be increased greatly.

Another object of the present invention is to provide a method for manufacturing a DSSC, which can be used to provide a DSSC with improved performance in a simple way.

To achieve the object, the DSSC of the present invention comprises: a dye-sensitized semiconductor electrode, a counter electrode opposite to the dye-sensitized semiconductor electrode, and an electrolyte disposed between the dye-sensitized semiconductor electrode and the counter electrode. Herein, the dye-sensitized semiconductor electrode comprises: an anode; a TiO₂ layer disposed on the anode; and a dye absorbed to the TiO₂ layer. In addition, the counter electrode comprises: a first transparent substrate with a first transparent electrode formed thereon; and a Pt film disposed on the first transparent electrode, wherein the Pt film is formed with plural Pt nanoparticles, the diameters of the Pt nanoparticles are 1-8 nm, and the thickness of the Pt film is 0.5-3 nm.

In addition, the present invention also provides a method for manufacturing the aforementioned dye-sensitized solar cell, which comprises the following steps: (A) providing a dye-sensitized semiconductor electrode, which comprises: an anode; a TiO₂ layer formed on the anode; and a dye absorbed to the TiO₂ layer; (B) providing a first transparent substrate with a first transparent electrode formed thereon, and forming a Pt film on the first transparent electrode, wherein the Pt film is formed with plural Pt nanoparticles, the diameters of the Pt nanoparticles are 1-8 nm, and the thickness of the Pt film is 0.5-3 nm; and (C) forming an electrolyte between the dye-sensitized semiconductor electrode and the counter electrode, wherein the TiO₂ layer faces to the Pt film.

According to the DSSC and the method for manufacturing the same of the present invention, the particle sizes of the Pt nanoparticles in the Pt film and the thickness of the Pt film are both in nano-scale. Hence, the Pt film has not only high catalytic activity but also high light transmittance. Therefore, the light can illuminate to the DSSC of the present invention through both sides (i.e. the front side and the back side) of the device due to the high light transmittance of the Pt film, so the performance of the DSSC can further be improved. In addition, the DSSC of the present invention can also be used as a backside illumination DSSC, in which the anode used in the dye-sensitized semiconductor electrode is a metal foil. Hence, the problem that the flexible substrate cannot endure high temperature during the process of forming TiO₂ layer can be solved.

According to the DSSC and the method for manufacturing the same of the present invention, the diameter of the Pt nanoparticles are in nano-scale. As the particle sizes of the Pt nanoparticles are decreased, the total surface area of the Pt nanoparticles can be increased. Hence, the catalytic activity of the Pt film can be improved. Preferably, the diameters of the Pt nanoparticles are 1-5 nm. More preferably, the average diameters of the Pt nanoparticles are 1-8 nm. Most preferably, the average diameters of the Pt nanoparticles are 1-5 nm.

In addition, according to the DSSC and the method for manufacturing the same of the present invention, the thickness of the Pt film is 1-2 nm, preferably. Furthermore, in one aspect of the present invention, the coverage of the Pt nanoparticles on the first transparent electrode is 50-70%. Preferably, the coverage of the Pt nanoparticles on the first transparent electrode is 55-65%. Hence, the Pt film of the DSSC of the present invention has not only high catalytic activity but also high light transmittance.

According to the method for manufacturing the DSSC of the present invention, the Pt film is formed through a sputtering process in the step (B). Preferably, the Pt film is formed through an ion-sputtering process. Herein, the sputtering current of the sputtering process can be 40-100 mA, the pressure of the sputtering process can be 10⁻²-10⁻³ torr, the sputtering time of the sputtering process can be 6-20 sec, and the deposition rate of the sputtering process can be 0.05-0.15 nm/sec.

In addition, according to the DSSC and the method for manufacturing the same of the present invention, the anode can be a second transparent substrate with a second transparent electrode formed thereon, or a metal foil. When the anode is a second transparent substrate with a second transparent electrode formed thereon, the light can illuminate through the both sides of the DSSC. When the anode is a metal foil, the light can only illuminate through the backside (i.e. the counter electrode) of the DSSC. In the present invention, the second transparent substrate of the anode or the first transparent substrate of the counter electrode can be any transparent plastic substrate or glass substrate used in the art. Preferably, the second transparent substrate of the anode or the first transparent substrate of the counter electrode is a transparent plastic substrate such as a PET substrate, a PEN substrate, a PC substrate, a PP substrate, or a PI substrate. Furthermore, the metal foil can be any metal material that can be used as an electrode, such as a Ti substrate. When the substrate of the anode and the counter electrode are flexible substrate such as plastic substrate or a metal foil, a flexible DSSC can be obtained.

In addition, the first transparent electrode and the second transparent electrode used in the present invention can be an ITO electrode, an IZO electrode, or an FTO (SnO₂:F) electrode

In one aspect of the present invention, the DSSC of the present invention further comprises a reflective plate placed on the side of the DSSC and facing to the counter electrode. When the light illuminates from the front side (i.e. the dye-sensitized semiconductor electrode), the light, which is un-absorbed by the dyes and passes through the counter electrode, can be reflected by the reflective plate and absorbed by the dyes. In another aspect of the present invention, the reflective plate may also be placed on the side of the DSSC and face to the dye-sensitized semiconductor electrode. When the light illuminates from the backside (i.e. the counter electrode), the light, which is un-absorbed by the dyes and passes through the dye-sensitized semiconductor electrode, can be reflected by the reflective plate and absorbed by the dyes. Therefore, the efficiency of the DSSC of the present invention can further be increased. The example of the reflective plate is an aluminum foil.

Furthermore, when more than two DSSCs of the present invention are used together, at least one reflective plate can further be placed between two adjacent DSSCs. Preferably, one surface of the reflective plate faces to a counter electrode of a DSSC, and the other surface of the reflective plate faces to a dye-sensitized semiconductor electrode of the adjacent DSSC.

According to the method for manufacturing the DSSC of the present invention, the TiO₂ layer can be a porous TiO₂ layer with holes in nano size. The TiO₂ layer can be formed by a spin coating process, a roll coating process, a printing process, a dip coating process. In addition, the dye used in the present invention can be any dyes generally used in the art, such as N3 dyes, N712 dyes, N719 dyes, N749 dyes. Furthermore, the electrolyte used in the present invention can be any liquid electrode generally used in the art, such as I⁻/I₃⁻ electrolyte.

Other objects, advantages, and novel features of the invention will become more apparent from the following detailed description when taken in conjunction with the accompanying drawings.

### BRIEF DESCRIPTION OF THE DRAWINGS

FIGS. 1A-1C are cross-sectional views showing the process for manufacturing a dye-sensitized solar cell of the Embodiment 1 of the present invention;

FIG. 2 is a cross-sectional view of a dye-sensitized solar cell of the Embodiment 3 of the present invention;

FIG. 3 is a cross-sectional view of a dye-sensitized solar cell of the Embodiment 4 of the present invention;

FIG. 4 is a cross-sectional view of a dye-sensitized solar cell of the Embodiment 5 of the present invention; and

FIG. 5 is a cross-sectional view of a dye-sensitized solar cell of the Embodiment 7 of the present invention.

### DETAILED DESCRIPTION OF THE PREFERRED EMBODIMENT

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

### Embodiment 1

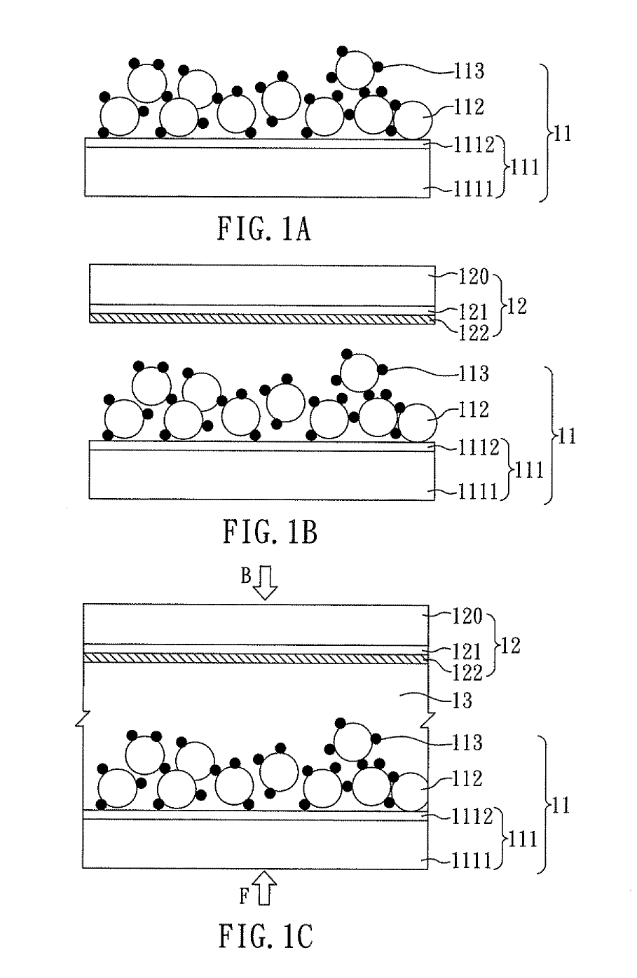

FIGS. 1A-1C are cross-sectional views showing the process for manufacturing a dye-sensitized solar cell of the present embodiment.

As shown in the FIG. 1A, a dye-sensitized semiconductor electrode 11 was provided, which comprised: an anode 111; a TiO₂ layer 112 formed on the anode 111; and a dye 113 absorbed to the TiO₂ layer 112.

The process for forming the dye-sensitized semiconductor electrode 11 is described as follow. First, the anode 111 was a second transparent substrate 1111 with a second transparent electrode 1112 formed thereon. In the present embodiment, the second transparent substrate 1111 was a glass substrate, and the second transparent electrode 1112 was an ITO electrode (8Ω/□, AimCoreTechnology Co., Ltd).

Then, TiO₂ paste (Degussa P25) was spin coating on the anode 111 and followed by sintering at 450° C. for 30 min to obtain a TiO₂ layer 112 with a thickness of 12 μm shown in the FIG. 1A. Next, the TiO₂ layer 112 was immersed in ethanol solution containing 0.3 mM ruthenium-535-bis-TBA (Solaronix, N719 dye) for 20-24 h at room temperature, followed by rinsing with ethanol. After the aforementioned process, a dye-sensitized semiconductor electrode 11 was obtained, as shown in the FIG. 1A.

Then, as shown in the FIG. 1B, a first transparent substrate 120 with a first transparent electrode 121 formed thereon was provided. Herein, the first transparent substrate 120 was a glass substrate, and the first transparent electrode 121 was an ITO electrode (8Ω/□, AimCoreTechnology Co., Ltd).

Next, a Pt film 122 was formed on the first transparent electrode 121 using a DC sputtering equipment (Gressington 108 auto, Ted Pella, USA), and a counter electrode 12 was obtained. The Pt deposition was performed at a sputtering current of 40 mA under a base pressure of 10⁻³ torr. The deposition rate corresponding to this operation conditions was measured to be 0.11±0.005 nm/sec. In addition, the time of the sputtering process was 13 sec. After the sputtering process, plural Pt nanoparticles were deposited on the first transparent electrode 121 to form a Pt film 122, as shown in the FIG. 1B. In the present embodiment, the average diameters of the Pt nanoparticles are 1-4 nm, the thickness of the Pt film is 1.4 nm, and the coverage of the Pt nanoparticles on the first transparent electrode 121 is 60%.

As shown in the FIG. 1C, an electrolyte 13 was formed between the dye-sensitized semiconductor electrode 11 and the counter electrode 12, wherein the TiO₂ layer 112 faced to the Pt film 122. In the present embodiment, an acetonitrile solution containing 0.1 M LiI, 0.05 M I₂, 0.5 M 4-tert-butylpyridine (TBP), and 0.5 M 1-propyl-2,3-dimethyl-imidazolium iodine (DMPII) was used as the electrolyte 13. In addition, the dye-sensitized semiconductor electrode 11 and the counter electrode 12 were sandwiched using a 30 μm thick sealing material (SX-1170-60, Solaronix SA).

After the aforementioned process, a dye-sensitized solar cell of the present embodiment was obtained, which comprises: a dye-sensitized semiconductor electrode 11, a counter electrode 12 opposite to the dye-sensitized semiconductor electrode 11, and an electrolyte 13 disposed between the dye-sensitized semiconductor electrode 11 and the counter electrode 12. In the DSSC of the present embodiment, the dye-sensitized semiconductor electrode 11 comprises: an anode 111; a TiO₂ layer 112 disposed on the anode 111; and a dye 113 absorbed to the TiO₂ layer 112. In addition, the counter electrode 12 comprises: a first transparent substrate 120 with a first transparent electrode 121 formed thereon; and a Pt film 122 disposed on the first transparent electrode 121, wherein the Pt film 122 is formed with plural Pt nanoparticles, the average diameters of the Pt nanoparticles are 1-4 nm, and the thickness of the Pt film 122 is 1.4 nm.

### Embodiment 2

The method for manufacturing the DSSC of the present embodiment is the same as that described in the Embodiment 1, except that the time of the sputtering process was 6 sec. Therefore, in the DSSC of the present embodiment, the Pt film has a thickness of 0.6 nm, the average diameters of the Pt nanoparticles are 1-2 nm, and the coverage of the Pt nanoparticles on the first transparent electrode is about 41%.

### Comparative Embodiment 1

The method for manufacturing the DSSC of the present comparative embodiment is the same as that described in the Embodiment 1, except that the time of the sputtering process was 105 sec. Therefore, in the DSSC of the present comparative embodiment, the Pt film has a thickness of 12.3 nm, the average diameters of the Pt nanoparticles are more than 10 nm, and the coverage of the Pt nanoparticles on the first transparent electrode is about 100%.

### Evaluation the Performance of the DSSCs of the Embodiments 1-2 and the Comparative Embodiment 1

The DSSCs prepared in the Embodiments 1-2 and the Comparative embodiment 1 were measured under one sun illumination (AM1.5, 100 mW/cm²). The related parameters obtained from the I-V curves, that the DSSCs are illuminated from the front side (as the direction F shown in the FIG. 1C), are shown in the following Table 1.

TABLE 1

| | Pt film | | | | |
|---|---|---|---|---|---|
| | Thickness | I_{sc} | | | |
| | (nm) | (mA/cm²) | V_{oc} (mV) | ff | η (%) |
| Embodiment 1 | 1.4 | 15.08 | 742.2 | 0.65 | 7.28 |
| Embodiment 2 | 0.6 | 14.86 | 703.3 | 0.65 | 6.80 |
| Comparative | 12.3 | 14.19 | 741.4 | 0.64 | 6.77 |
| embodiment 1 | | | | | |

For the front-side illumination, the Pt film of the Embodiment 1 demonstrates higher overall efficiency (η=7.3%) than that of the Comparative embodiment 1 (η=6.8%).

In addition, electrochemical impedance spectroscopy (EIS) analysis was used to elucidate the charge-transfer resistance at the counter electrode/electrolyte interface (R_{ct}) of the Embodiment 1 and the Comparative embodiment 1. The R_{ct} measured for the Pt film of the Embodiment 1 is as low as 0.45 Ω/cm², which is about 64% the value of that of the Comparative embodiment 1 (0.7 Ω/cm²).

Furthermore, the light transmittance analysis was also performed on the counter electrode of the Embodiment 1 and the Comparative embodiment 1. The results show that the counter electrode of the Embodiment 1 has a mean transmittance as high as 76% in the visible light region, which is only slightly lower than that of the bare ITO substrate (83%). However, the counter electrode of the Comparative embodiment 1 has a mean transmittance of 27%, which is much lower than that of the counter electrode of the Embodiment 1. Therefore, the counter electrode of the Embodiment 1 has high light transmittance, so the DSSC of the Embodiment 1 can be used as a back-side illumination DSSC.

The performances of the back-illuminated DSSCs under one sun illumination are also evaluated. The related parameters obtained from the I-V curves, that the DSSCs are illuminated from the back side (as the direction B shown in the FIG. 1C), are shown in the following Table 2.

TABLE 2

| | Pt film | | | | |
|---|---|---|---|---|---|
| | Thickness | I_{sc} | | | |
| | (nm) | (mA/cm²) | V_{oc} (mV) | ff | η (%) |
| Embodiment 1 | 1.4 | 11.8 | 739 | 0.68 | 5.9 |
| Embodiment 2 | 0.6 | 11.8 | 699 | 0.68 | 5.6 |
| Comparative | 12.3 | 5.2 | 708 | 0.70 | 2.6 |
| embodiment 1 | | | | | |

The I_{sc}, measured for the DSSC of the Comparative embodiment 1 is only 5.2 mA/cm², ascribed to the low transmittance of the Pt film. However, the I_{sc} and efficiency of the Embodiments 1 and 2 are increased, due to the high light transmittance of the counter electrode. The Pt film of the Embodiment 1 also demonstrates higher overall efficiency (η=5.9%) than that of the Comparative embodiment 1 (η=2.6%). This result indicates that the counter electrode of the Embodiment 1 has the good performance by considering both the charge transfer and light transmittance.

### Embodiment 3

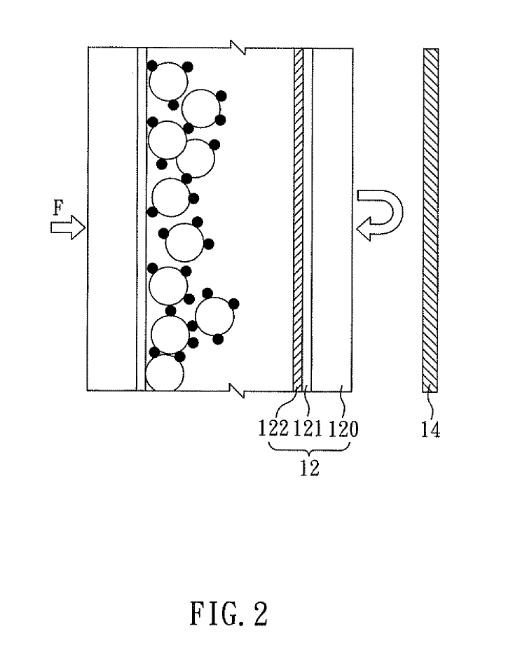

FIG. 2 is a cross-sectional view of a dye-sensitized solar cell of the present embodiment.

The method for manufacturing the DSSC of the present embodiment is the same as that described in the Embodiment 1, except that an aluminum foil 14 is placed on the side of the DSSC and face to the counter electrode 12.

Evaluation the Performance of the DSSCs of the Embodiment 1 and the Embodiment 3 by Illuminating Light from the Front Side

The DSSCs prepared in the Embodiments 1 and 3 were measured under one sun illumination (AM1.5, 100 mW/cm²). The related parameters obtained from the I-V curves, that the DSSCs are illuminated from the front side (as the direction F shown in the FIG. 2), are shown in the following Table 3.

TABLE 3

| | Pt film | | | | |
|---|---|---|---|---|---|
| | Thickness | I_{sc} | | | |
| | (nm) | (mA/cm²) | V_{oc} (mV) | ff | η (%) |
| Embodiment 1 | 1.4 | 15.08 | 742.2 | 0.65 | 7.28 |
| Embodiment 3 | 1.4 | 16.4 | 752 | 0.64 | 7.9 |

For a highly transparent counter electrode, the un-absorbed light may be lost through the counter electrode under front-side illumination. According to the results shown in Table 3, the efficiency of the DSSC of the Embodiment 3 (7.9%) is better than that of the Embodiment 1 (7.28%) under front-side illumination. Hence, aluminum foil can be used as a reflective plate to enhance the performance of the DSSCs.

### Embodiment 4

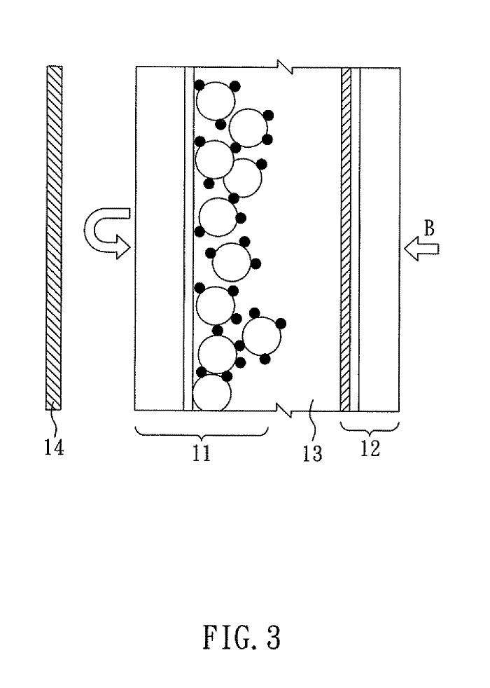

FIG. 3 is a cross-sectional view of a dye-sensitized solar cell of the present embodiment.

The method for manufacturing the DSSC of the present embodiment is the same as that described in the Embodiment 1, except an aluminum foil 14 is placed on the side of the DSSC and face to the dye-sensitized semiconductor electrode 11.

Evaluation the Performance of the DSSCs of the Embodiment 1 and the Embodiment 4 by Illuminating Light from the Backside

The DSSCs prepared in the Embodiments 1 and 4 were measured under one sun illumination (AM1.5, 100 mW/cm²). The related parameters obtained from the I-V curves, that the DSSCs are illuminated from the back side (as the direction B shown in the FIG. 3), are shown in the following Table 4.

TABLE 4

| | Pt film | | | | |
|---|---|---|---|---|---|
| | Thickness | I_{sc} | | | |
| | (nm) | (mA/cm²) | V_{oc} (mV) | ff | η (%) |
| Embodiment 1 | 1.4 | 11.8 | 739 | 0.68 | 5.9 |
| Embodiment 4 | 1.4 | 13.1 | 745 | 0.68 | 6.6 |

For the backside illumination, the un-absorbed light cannot be reflected from the dye-sensitized semiconductor electrode, which is a transparent electrode. According to the results shown in Table 4, the efficiency of the DSSC of the Embodiment 4 (6.6%) is better than that of the Embodiment 1 (5.9%) under backside illumination. Hence, aluminum foil can be used as a reflective plate to enhance the performance of the DSSCs.

### Embodiment 5

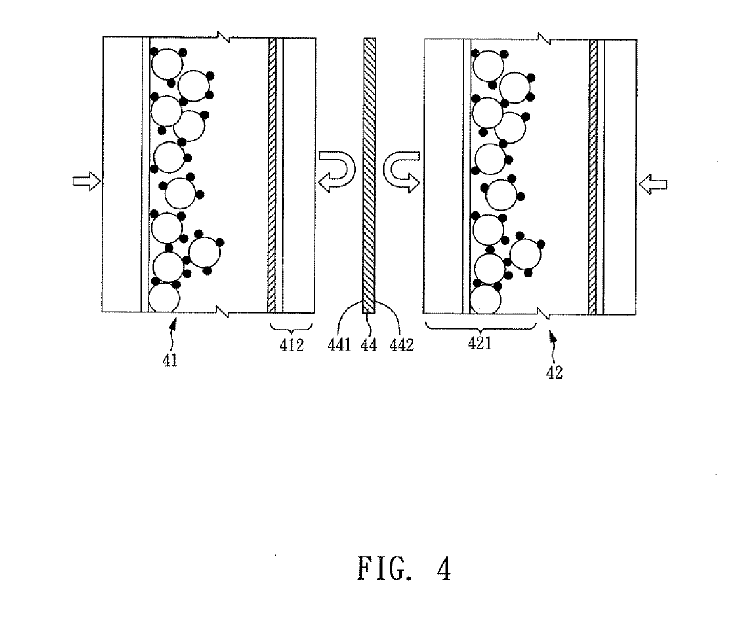

FIG. 4 is a cross-sectional view of a dye-sensitized solar cell of the present embodiment.

As shown in the FIG. 4, two DSSCs 41, 42 prepared according to the Embodiment 1 are used together, and a reflective plate 44 is placed between these two adjacent DSSCs 41, 42. Hence, for the front-side illumination, the un-absorbed light passing through the counter electrode 412 of one DSSC 41 can be reflected by the first surface 441 of the reflective plate 44. In addition, for the backside illumination, the un-absorbed light passing through the dye-sensitized semiconductor electrode 421 can also be reflected by the second surface 442 of the reflective plate 44. Therefore, the efficiency of the both DSSCs can be improved.

### Embodiment 6

The method for manufacturing the DSSC of the present embodiment are the same as those described in the Embodiment 1, except that first transparent substrate 120 and the second transparent substrate 1111 are PEN substrates, and the process for sintering the TiO₂ layer is 140° C.

The obtained DSSC of the present embodiment is a flexible DSSC, which can be manufactured through a roll-to-roll process.

### Embodiment 7

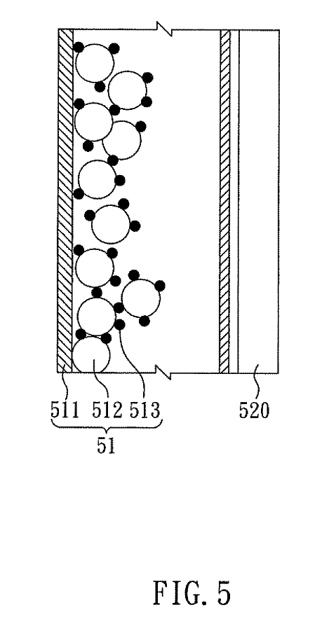

The method for manufacturing the DSSC of the present embodiment are the same as those described in the Embodiment 1, except that the anode of the Embodiment 1 is substituted with a metal foil, and the first transparent substrate is a plastic substrate. Hence, the dye-sensitized semiconductor electrode 51 of the present embodiment comprises an anode 511 made of a metal foil; a TiO₂ layer 512 disposed on the anode 511; and a dye 513 absorbed to the TiO₂ layer 512. In the present embodiment, the metal foil is a Ti foil, as shown in the FIG. 5.

The light cannot transmit through the anode 511 of the dye-sensitized semiconductor electrode 51 of the present embodiment, so the obtained DSSC is a backside illumination DSSC.

In addition, the metal foil used in the anode 511 and the plastic substrate used as the first transparent substrate 521 are flexible, so the obtained DSSC of the present embodiment is a flexible DSSC, which can be manufactured through a roll-to-roll process.

Although the present invention has been explained in relation to its preferred embodiment, it is to be understood that many other possible modifications and variations can be made without departing from the spirit and scope of the invention as hereinafter claimed.

What is claimed is:

1. A dye-sensitized solar cell, comprising:
a dye-sensitized semiconductor electrode, which comprises:
an anode;
a TiO₂ layer disposed on the anode; and
a dye absorbed to the TiO₂ layer;
a counter electrode opposite to the dye-sensitized semiconductor electrode, wherein the counter electrode comprises:
a first transparent substrate with a first transparent electrode formed thereon; and
a Pt film disposed on the first transparent electrode, wherein the Pt film is formed with plural Pt nanoparticles, the diameters of the Pt nanoparticles are 1-8 nm, and the thickness of the Pt film is 0.5-3 nm; and
an electrolyte disposed between the dye-sensitized semiconductor electrode and the counter electrode.

2. The dye-sensitized solar cell as claimed in claim 1, wherein the Pt film is a Pt film with high light transmittance.

3. The dye-sensitized solar cell as claimed in claim 1, wherein the diameters of the Pt nanoparticles are 1-5 nm.

4. The dye-sensitized solar cell as claimed in claim 3, wherein the average diameters of the Pt nanoparticles are 1-5 nm.

5. The dye-sensitized solar cell as claimed in claim 3, wherein the thickness of the Pt film is 1-2 nm.

6. The dye-sensitized solar cell as claimed in claim 4, wherein the coverage of the Pt nanoparticles on the first transparent electrode is 50-70%.

7. The dye-sensitized solar cell as claimed in claim 1, wherein the anode is a second transparent substrate with a second transparent electrode formed thereon, or a metal foil.

8. The dye-sensitized solar cell as claimed in claim 7, wherein the second transparent substrate is a transparent plastic substrate, and the metal foil is a Ti substrate.

9. The dye-sensitized solar cell as claimed in claim 1, wherein the first transparent substrate is a transparent plastic substrate.

10. A method for manufacturing a dye-sensitized solar cell, comprising the following steps:
(A) providing a dye-sensitized semiconductor electrode, which comprises: an anode; a TiO₂ layer formed on the anode; and a dye absorbed to the TiO₂ layer;
(B) providing a first transparent substrate with a first transparent electrode formed thereon, and forming a Pt film on the first transparent electrode, wherein the Pt film is formed with plural Pt nanoparticles, the diameters of the Pt nanoparticles are 1-8 nm, and the thickness of the Pt film is 0.5-3 nm; and
(C) forming an electrolyte between the dye-sensitized semiconductor electrode and the counter electrode, wherein the TiO₂ layer faces to the Pt film.

11. The method as claimed in claim 10 wherein the Pt film is a Pt film with high light transmittance.

12. The method as claimed in claim 10 wherein the Pt film is formed through a sputtering process in the step (B).

13. The method as claimed in claim 12, wherein the sputtering current of the sputtering process is 40-100 mA.

14. The method as claimed in claim 12, wherein the pressure of the sputtering process is 10⁻²-10⁻³ torr.

15. The method as claimed in claim 12, wherein the time of the sputtering process is 6-20 sec.

16. The method as claimed in claim 10, wherein the diameters of the Pt nanoparticles are 1-5 nm.

17. The method as claimed in claim 10, wherein the average diameters of the Pt nanoparticles are 1-5 nm.

18. The method as claimed in claim 10, wherein the thickness of the Pt film is 1-2 nm.

19. The method as claimed in claim 17, wherein the coverage of the Pt nanoparticles on the first transparent electrode is 50-70%.

20. The method as claimed in claim 10, wherein the anode is a second transparent substrate with a second transparent electrode formed thereon, or a metal foil.

21. The method as claimed in claim 20, wherein the second transparent substrate is a transparent plastic substrate, and the metal foil is a Ti substrate.

22. The method as claimed in claim 10, wherein the first transparent substrate is a plastic substrate.
